(19) United States
(12) Patent Application Publication
(10) Pub. No.: US 2010/0007374 A1
(43) Pub. Date: Jan. 14, 2010

(54) ON-DIE THEVENIN TERMINATION FOR HIGH SPEED I/O INTERFACE

(75) Inventors: Rajat Chauhan, Dehradun (IN); Karthik Rajagopal, Bangalore (IN); Vinod Menezes, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/172,282

(22) Filed: Jul. 14, 2008

(51) Int. Cl. H03K 17/16

(52) U.S. Cl. 326/30

(57) ABSTRACT

The method, system, and apparatus of on-die Thevenin termination for high speed I/O interface are disclosed. In one embodiment, a system of terminating a transmission line of a chip includes a pull-up circuit located within the chip comprising a voltage source and a positive switch device coupled with the transmission line of the chip, a pull-down circuit located within the chip comprising a ground and a negative switch device coupled with the transmission line of the chip, a resistor located within the chip coupled with the voltage source, the positive switch device, the ground, the negative switch device, and a pad coupled with the resistor to terminate the transmission line of the chip. The system may include resistors coupled in parallel with each other. The system may include an impedance module to determine a load impedance value as seen from the pad that matches a source impedance value.

### FIELD OF TECHNOLOGY

This disclosure relates generally to an enterprise method, a technical field of software and/or hardware technology and, in one example embodiment, an on-die Thevenin termination for high speed I/O interface.

### BACKGROUND

A set of chips (e.g. an integrated circuit made out of a semiconductor material) may be coupled with a set of passive components (e.g. a set of metallic wires that couple the electronic components, etc.) located on a pad area (e.g. a flat surface used to make an electrical contact, a motherboard). The pad area may be overcrowded with electronic and/or passive components. An overcrowding of the pad area may lead to an increase in cost of manufacturing by enlarging a pad area's size and/or complexity. An overcrowding of a pad area may also increase a parasitic capacitance value (e.g. an unwanted capacitance that exists between the parts of an electronic circuit due to a proximity of a number of components) of the pad area. If the parasitic capacitance value increases above a specified threshold, it may affect chip and/or pad area performance.

A final-stage pad driver (e.g. an electronic component used to control the chip/pad interface) may be used for the on-die termination method (e.g. a termination resistor for impedance matching in a set of transmission lines). Within the final-stage pad driver, a same structure may both transmit the signal and provide an on-die termination (e.g. may be both a source and a load). This structure may include a configuration of leg structures. Each leg structure may comprise a pull-up component (e.g. a positive switch coupled in series to a resistor) and a pull-down component (e.g. a negative switch coupled in series to another resistor). The two resistors of each of the leg structures may be in parallel.

The final-stage pad driver may use impedance matching (e.g. matching an output impedance of a source equal to an input impedance of a load with which it may be coupled) in an assembly of transmission lines (e.g. a signal line, a material medium that forms a path directing a transmission of a signal) that are located inside the chip instead of the pad area. However, due to an inherent manufacturing variation in an impedance value of each individual resistor, an impedance match may not occur. Lack of the impedance match may decrease signal power. Consequently, a signal transmission operation of the chip may not function optimally.

The parasitic capacitance may also partially be a function of a number of electronic components in a locality of the chip. Thus, a threshold number of resistors in the final-stage pad driver may increase the parasitic capacitance value of the chip and in turn increase the parasitic capacitance value of the electronic circuit. Also, increasing the threshold number of resistors used may increase the size of the chip and/or may lead a chip designer to not use other components in order to save a chip space. Other chip operations may be reduced in effectiveness as the space for their implementation is decreased in order to compensate for the use of the threshold number of resistors. Finally, increasing the threshold number of resistors may increase the cost of manufacturing the set of chips by increasing a components cost.

### SUMMARY

The method, system, and apparatus of on-die Thevenin termination for high speed I/O interface are disclosed. In one aspect, a system of terminating a transmission line of a chip includes a pull-up circuit located within the chip comprising a voltage source and a positive switch device (e.g., may be a p-channel metal-oxide-semiconductor field-effect transistor (MOSFET) device used to switch electronic signals) coupled with the transmission line of the chip, a pull-down circuit located within the chip comprising a ground and a negative switch device (e.g., may be an n-channel MOSFET device used to switch electronic signals) coupled with the transmission line of the chip, a resistor located within the chip coupled with the voltage source, the positive switch device, the ground, the negative switch device, and a pad coupled with the resistor to terminate the transmission line of the chip.

The system may include resistors coupled in parallel with each other and each resistor is coupled with a corresponding pull-up circuit and/or a corresponding pull-down circuit. The system may also include an impedance module to determine a load impedance value as seen from the pad that matches a source impedance value. The resistors may be an even number of resistors. In addition, the system may include a command module to operate half of the pull-up circuits in an on mode while simultaneously operating an equal even number of pull-down circuits in an off mode. A pull-up circuit and/or a pull-down circuit coupled to the resistor may not be both simultaneously be in the on mode.

A specified even number of pull-up circuits, pull-down circuits and resistors of a particular impedance value may be used to obtain the load impedance value as seen from the pad. All the pull-up circuits in the on mode and all the pull down circuits may be operated in the off mode, and an impedance value of the in parallel resistors may match a specified load impedance value. All the pull-up circuits in the off mode and/or all the pull down circuits may be operated in the on mode, and the impedance value of the in parallel resistors in parallel may match a specified load impedance value.

In another aspect, a method of an on-die termination (ODT) circuit of a semiconductor integrated circuit includes configuring a leg of the ODT circuit by coupling a positive electrical switch with a resistor and coupling the resistor with a negative electrical switch, coupling the leg with a voltage source, coupling the leg with a ground, locating the leg within the semiconductor integrated circuit, associating the positive electrical switch with a positive electronic signal line (e.g. a transmission line) of the integrated circuit, associating the negative electrical switch with a negative electronic signal line (e.g. a transmission line) of the integrated circuit, and coupling the resistor to a circuit board.

The method may include legs configured such that all the resistors have a same potential difference across each end of the resistors. The method may include associating the legs with a command module. The command module may control the mode of operation of the legs by turning on any one of the positive electrical switches and/or the negative electrical switches. The positive electrical switches of the legs may be turned on by the command module, and the negative electrical switches of the legs may be turned off by the command module. The negative electrical switches of the legs may be turned on by the command module, and the positive electrical switches of the legs may be turned off by the command module.

The legs may be even in number. Half the positive electrical switches of a half of the legs may be turned on by the command module while the negative electrical switches of the half of the legs may be turned off by the command module. The negative electrical switches of an other half of the legs may be turned on by the command module while the positive electrical switches of the other half of the legs may be turned off by the command module. A thevenin-equivalent resistance value of the ODT circuit as seen from an pad may be equal with a specified source resistance value.

In yet another aspect, a method of a circuit technique includes configuring a number of legs (e.g., the number of legs may be an even number) of a chip pad driver with a pull-up component comprising a voltage source, a positive switch device and a resistor and with a pull-down component comprising a ground, a negative switch device and the resistor, locating the number of legs in the chip pad driver, associating an entirety of the resistors of the number of legs in parallel with each other, coupling the number of legs with a chip transmission line, and coupling the entirety of the resistors of the number of legs to a pad.

The method may include operating a half of an even number of legs with the positive switch device in an on-state and/or the negative switch device in an off-state. The method may operate an other half of the even number of legs with the positive switch device in an off-state and the negative switch device in an on-state. The method may include operating a specified even number of legs to obtain a load impedance value as seen from the pad equal to a specified source impedance value. The method may also include operating all the legs with the positive switch device in an on-state and the negative switch device in an off-state. In addition, the method may include operating all the legs with the positive switch device in an off-state and the negative switch device in an on-state.

The methods, systems, and apparatuses disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a systematic view of a pad that includes an on-die termination circuit to terminate the transmission lines in the semiconductor integrated circuit chip, according to one embodiment.

FIG. 2 is an exploded view of the on-die termination circuit illustrated in FIG. 1, according to one embodiment.

FIG. 3 is a diagrammatic view illustrating various identical legs coupled to a pad through a resistor, according to one embodiment.

FIG. 4 is a systematic view of the Thevenin termination mode, according to one embodiment.

FIG. 5A is a systematic view of a driver mode ‘A’, according to one embodiment.

FIG. 5B is a systematic view of a driver mode ‘B’, according to one embodiment

FIG. 6 is a process flow of configuring and coupling the leg of the ODT (On-Die Termination) circuit, according to one embodiment.

FIG. 7A is a process flow of operating all the legs with the positive switch device in an off-state and the negative switch device in an on-state, according to one embodiment.

FIG. 7B is a continuation of process flow of FIG. 7A, illustrating additional operations, according to on embodiment.

Other features of the present embodiments will be apparent from the accompanying drawings and from the detailed description that follows.

### DETAILED DESCRIPTION

The method, system, and apparatus of on-die Thevenin termination for high speed I/O interface are disclosed. Although the present embodiments have been described with reference to specific example embodiments, it will be evident that various modifications and changes may be made to these embodiments without departing from the broader spirit and scope of the various embodiments.

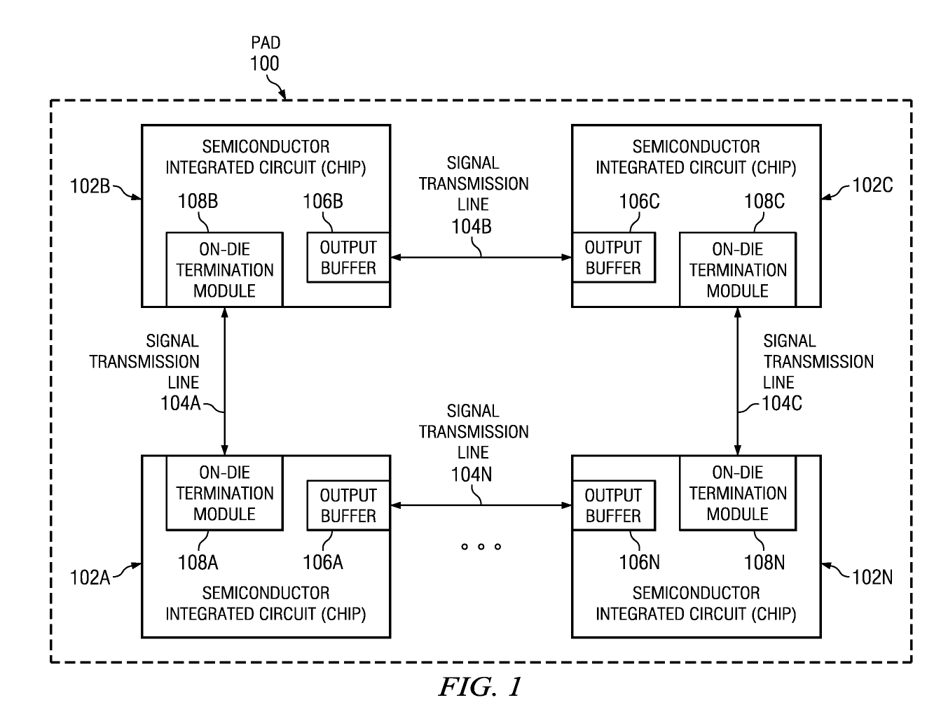

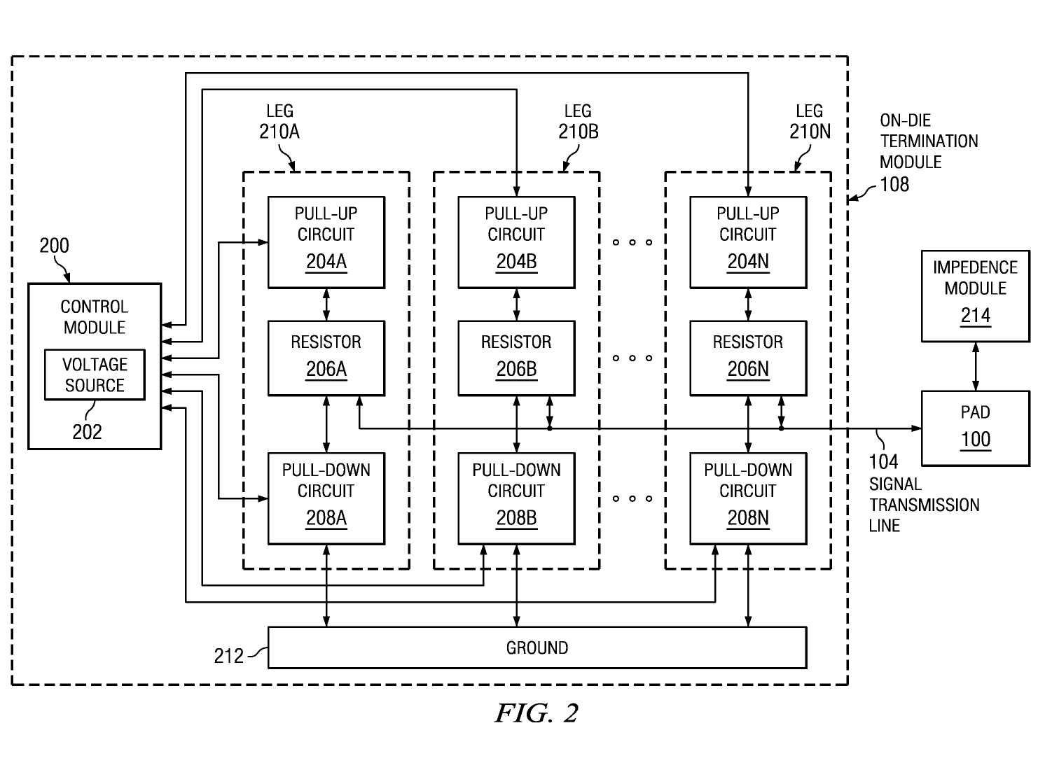

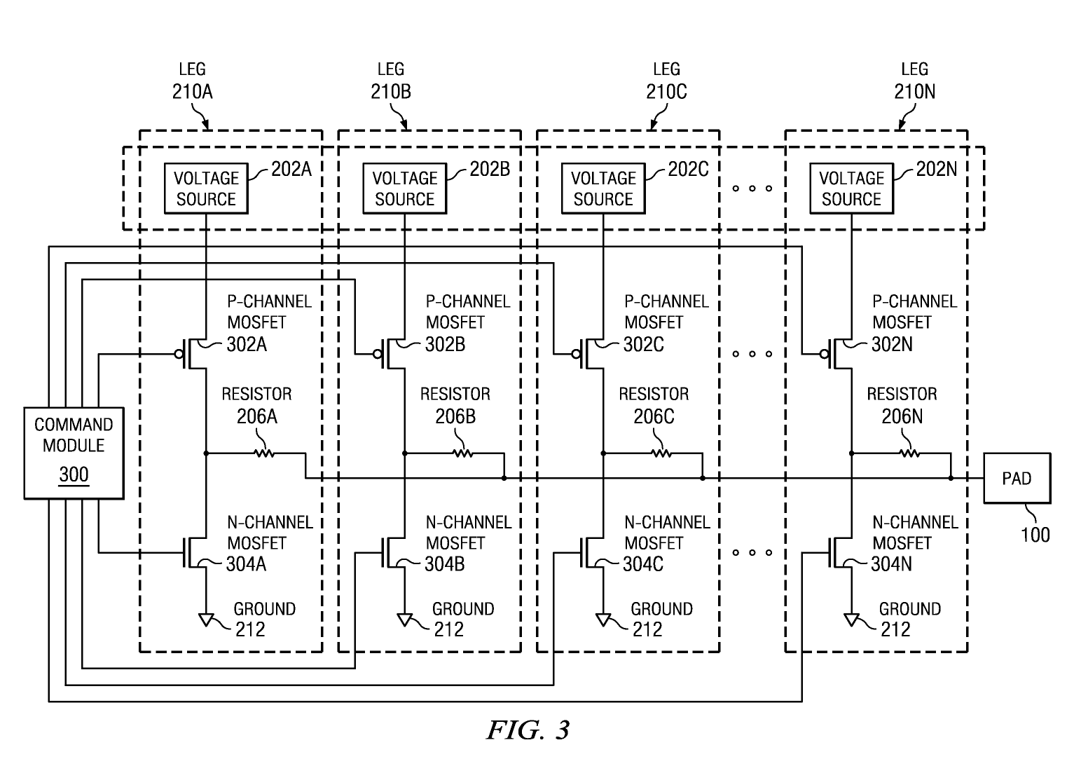

In one embodiment, a system of terminating a transmission line (e.g., the signal transmission line 104A-N of FIG. 1) of a chip (e.g., the semiconductor integrated circuit 102A-N of FIG. 1) includes a pull-up circuit (e.g., the pull-up circuit 204A-N of FIG. 2) located within the chip 102A-N comprising a voltage source (e.g., the voltage source 202 of FIG. 2) and a positive switch device (e.g., may be a p-channel metal-oxide-semiconductor field-effect transistor (MOSFET) device 302A-N of FIG. 3 used to switch electronic signals) coupled with the transmission line (e.g., the signal transmission line 104A-N) of the chip, a pull-down circuit located within the chip comprising a ground (e.g., the ground 210 of FIG. 2) and a negative switch device (e.g., may be an n-channel MOSFET device 304A-N of FIG. 3 used to switch electronic signals) coupled with the transmission line 104A-N of the chip 102A-N, a resistor (e.g., the resistor 206A-N of FIG. 2) located within the chip 102A-N coupled with the voltage source 202, the positive switch device, the ground 210, the negative switch device and a pad (e.g., the pad 100 of FIG. 1) coupled with the resistor 206A-N to terminate the transmission line 104A-N of the chip 102A-N.

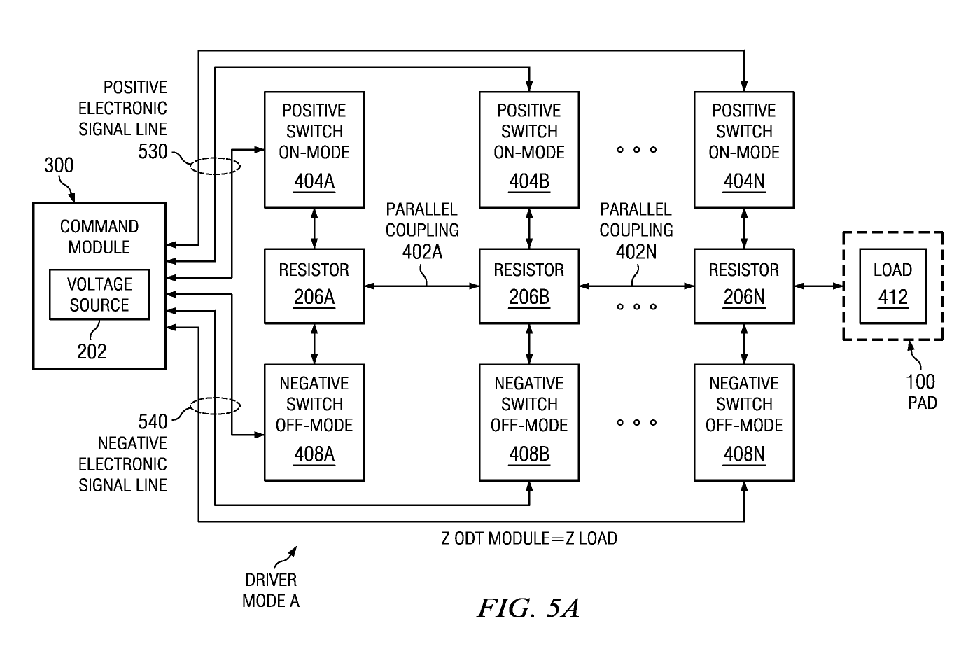

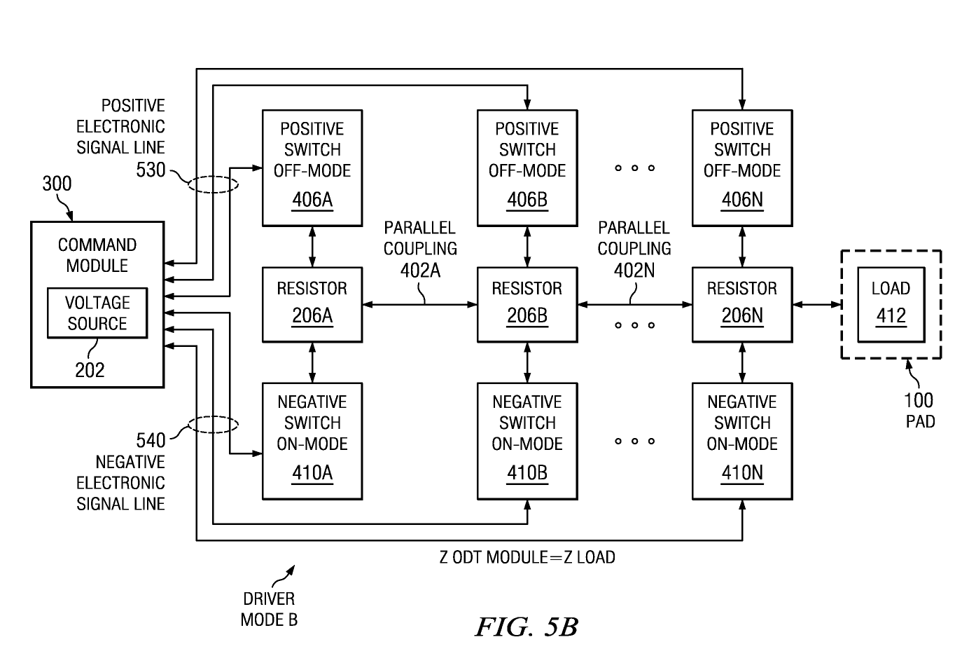

In another embodiment, a method of an on-die termination (ODT) circuit (e.g., the on-die termination circuit 108A-N of FIG. 1) of a semiconductor integrated circuit (e.g., the semiconductor integrated circuit 102A-N of FIG. 1) includes configuring a leg (e.g., the leg 210A-N of FIG. 2) of the on-die termination circuit 108A-N by coupling a positive electrical switch with a resistor 206A-N and coupling the resistor 206A-N with a negative electrical switch, coupling the leg 210A-N with a voltage source 202, coupling the leg 210A-N with a ground 210, locating the leg 210A-N within the semiconductor integrated circuit 102A-N, associating the positive electrical switch with a positive electronic signal line (e.g., the positive electronic signal line 530 of FIG. 5) of the integrated circuit 102A-N, associating the negative electrical switch with a negative electronic signal line (e.g., the negative electronic signal line 540 of FIG. 5) of the integrated circuit 102A-N, and coupling the resistor 206A-N to a circuit board (e.g., the semiconductor integrated circuit 102A-N of FIG. 1).

In yet another embodiment, a method of a circuit technique includes configuring a number of legs 210A-N (e.g., the number of legs may be an even number) of a chip pad driver with a pull-up component comprising a voltage source (e.g., the voltage source 202 of FIG. 2), a positive switch device (e.g., the p-channel metal-oxide-semiconductor field-effect transistor (MOSFET) device 302A-N of FIG. 3) and a resistor (e.g., the resistor 206A-N of FIG. 2) and with a pull-down component comprising a ground (e.g., the ground 210 of FIG. 2), a negative switch device (e.g., the n-channel MOSFET device 304A-N of FIG. 3) and the resistor 206A-N, locating the number of legs 210A-N in the chip pad driver, associating an entirety of the resistors 206A-N of the number of legs 210A-N in parallel with each other, coupling the number of legs 210A-N with a chip transmission line (e.g., the signal transmission line 104A-N of FIG. 1), and coupling the entirety of the resistors 206A-N of the number of legs 210A-N to a pad (e.g., the pad 100 of FIG. 1).

FIG. 1 is a systematic view of a pad that includes on-die termination circuit to terminate the transmission lines (e.g., the signal transmission line 104A-N of FIG. 1) in the semiconductor integrated circuit chip, according to one embodiment. Particularly, FIG. 1 illustrates a pad 100, a semiconductor integrated circuit (chip) 102A-N, a signal transmission line 104A-N, an output buffer 106A-N, and an on-die termination (ODT) circuit 108A-N, according to one embodiment.

The pad 100 may be a conductive platform (e.g., made up of copper, aluminum, etc.) to which components (e.g., a resistors, capacitors, etc.) may be coupled (e.g., through soldering) in an integrated circuits. The semiconductor integrated circuit (chip) 102A-N (e.g., known as IC, microcircuit, microchip, chip, etc.) may be a miniaturized electronic circuit (e.g., includes semiconductor devices, passive components, etc.) that may be the surface of a thin substrate of semiconductor material. The signal transmission line 104A-N (e.g., connecting tracks, etc.) may be an electronic transmission signal line (e.g., positive electronic signal line and/or negative electronic signal line) of a chip (e.g., the semiconductor integrated circuits, etc.) in which the output buffer takes place.

The output buffer 106A-N may be a memory to hold the output data temporarily processed by the signal transmission line in the chip (e.g., may be the semiconductor integrated circuit). The on-die termination (ODT) circuit 108A-N may configure the legs such that the termination circuit provides matching impedance to the load impedance for proper termination of transmission line (e.g., the signal transmission line 104A-N).

In example embodiment, FIG. 1 illustrates on-die termination circuit 108A-N that may terminate the transmission lines (e.g., the signal transmission line 104A-N) in the semiconductor integrated circuit (chip) 102A-N. The communication between the output buffer 106A-N may occur through the signal line 104A-N.

FIG. 2 is an exploded view of the on-die termination circuit 108A-N illustrated in FIG. 1, according to one embodiment. Particularly, FIG. 2 illustrates, the signal transmission line 104, the pad 100, a command module 200, a voltage source 202, a pull-up circuit 204A-N, a resistor 206A-N, a pull-down circuit 208A-N, a leg 210A-N, and a ground 212, according to one embodiment.

The command module 200 may be used to operate half of the pull-up circuits in the on mode and the equal even number of pull-down circuits in an off mode simultaneously. The voltage source 202 may be a device or system that produces an electromotive force between its circuits and/or derives a secondary voltage from a primary source of the electromotive force. The pull-up circuit 204A-N may be used to create default value (e.g., may pull the line high) for a circuit. The resistor 206A-N may be a two-terminal electronic component that opposes an electric current by producing a voltage drop between its terminals in proportion to the current. The pull-down circuit 208A-N may be used to create default value (e.g., may pull the line low) for a circuit.

The leg 210A-N may organize all the resistors 206A-N that may have a same potential difference across each end of the resistors 206A-N. The ground 212 may be the reference point in the circuits (e.g., may be integrated circuits, etc.) which may have zero voltage used for the safety purpose to limit the voltage in the circuits. The impedance module 214 may determine the load impedance value that may match with the source impedance value (e.g., as seen from the pad 100).

In example embodiment, FIG. 2 illustrates the on-die termination circuit 108 that may include the command module 200 that has the voltage source 202. The command module 200 may operate with the half of the pull-up circuits 204A-N in the on mode. Simultaneously, the command module 200 may operate with the equal number of pull-down circuits (e.g., of the pull-down circuits 208A-N) in an off mode. The resistor 206A-N coupled with the pad 100 may communicate with all the pull-up circuits' 204A-N and pull-down circuits' 208A-N which may not be simultaneously in the on mode. The leg 210A-N may be coupled with the voltage source 202, and the ground 210. The signal transmission line 104 may be coupled from the resistor 206A-N to the pad 100.

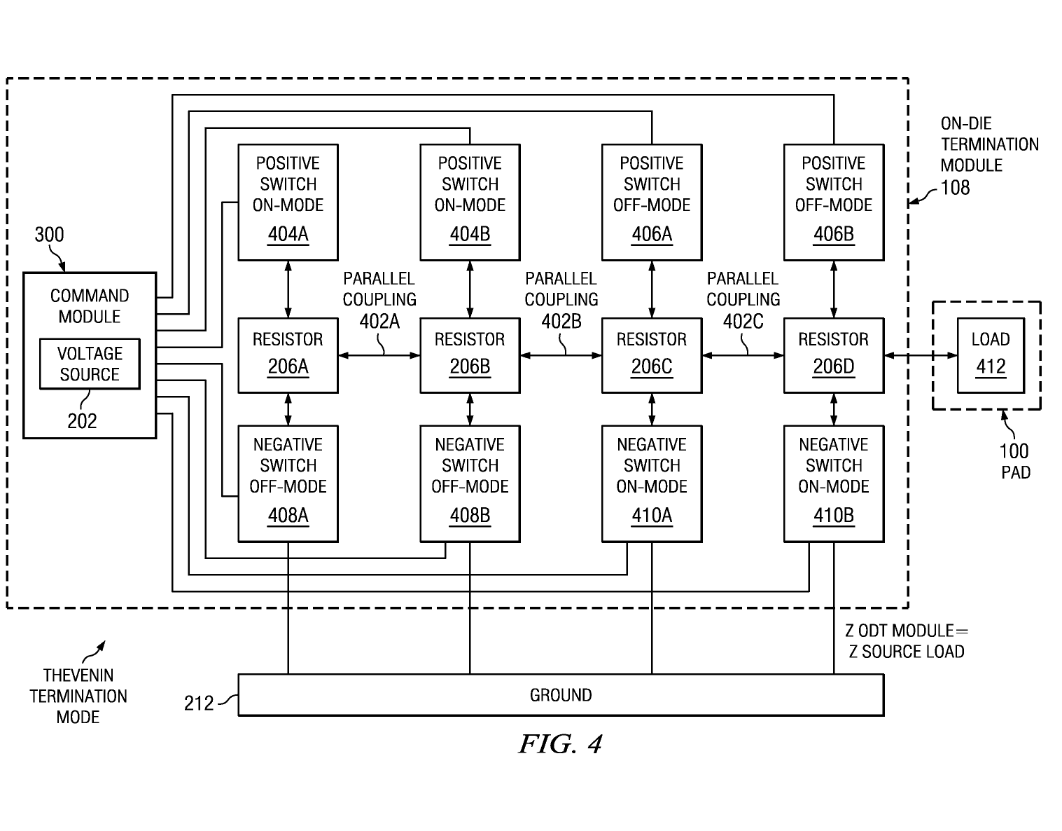

In one embodiment, The pull-up circuit located 204A-N within the chip (e.g., may be semiconductor integrated circuit 102A-N of FIG. 1) may include the voltage source 202 and/or the positive switch device (e.g., may have the positive switch on-mode 404A-B and the positive switch off-mode 406A-B of FIG. 4) coupled with the transmission line (e.g., the signal transmission line 104 of FIG. 1) of the chip. The pull-down circuit 208A-N located within the chip may include the ground 210 and the negative switch device coupled with the transmission line (e.g., the signal transmission line 104A-N) of the chip. The resistor 206A-N located within the chip may be coupled with the voltage source 202, the positive switch device, the ground, the negative switch device. The pad 100 may be coupled with the resistor 206A-N to terminate the transmission line (e.g., the signal transmission line 104A-N) of the chip. Resistors 206A-N may be coupled in parallel with each other and each resistor of resistors 206A-N may be coupled with the corresponding pull-up circuit (e.g., of the pull-up circuits 204A-N) and/or the corresponding pull-down circuit.

The impedance module 214 may determine the load impedance value as seen from the pad 100 that matches the source impedance value and the resistors 206A-N may be the even number of resistors. The command module 200 may operate half of the pull-up circuits 204A-N in the on mode while simultaneously operating the equal even number of pull-down circuits (e.g., of the pull-down circuits 208A-N) in the off mode and the pull-up circuit 204A and/or the pull-down circuit 208A-N coupled to the resistor 206A-N may not be both simultaneously be in the on mode. The specified even number of the pull-up circuits (e.g., of the pull-up circuits 204A-N), the pull-down circuits (e.g., of the pull-down circuits 208A-N) and/or the resistors 206A-N of the particular impedance value may be used to obtain the load impedance value as seen from the pad 100.

The all the pull-up circuits 204A-N in the on mode and/or all the pull-down circuits 208A-N may be operated in the off mode. The impedance value of the in parallel resistors matches the specified load impedance value. All the pull-up circuits 204A-N in the off mode and/or all the pull-down circuits 208A-N may be operated in the on mode. The impedance value of the in parallel resistors in parallel may match the specified load impedance value. The positive switch device may be a p-channel metal-oxide-semiconductor field-effect transistor (MOSFET) device used to switch electronic signals and/or the negative switch device may be an n-channel MOSFET device used to switch electronic signals.

The number of legs 210A-N of the chip (e.g., may be semiconductor integrated circuit 102A-N) pad driver may be configured with the pull-up component (e.g., may be pull-up circuit 204A-N) comprising the voltage source 202, the positive switch device (e.g., may be the positive switch on-mode 404A-N and the positive switch off-mode 406A-N) and the resistor 206A-N and with the pull-down component (e.g., may be pull-down circuit 208A-N) comprising the ground 210, the negative switch device (e.g., may be negative switch on-mode 410A-N and negative switch off-mode 408A-N) and the resistor 206A-N. The number of legs may be located in the chip pad driver. The entirety of the resistors 206A-N of the number of legs may be associated in parallel with each other. The number of legs may be coupled with the chip transmission line. The entirety of the resistors 206A-N of the number of legs may be coupled to the pad 100.

FIG. 3 is a diagrammatic view of circuits in the legs of a chip pad driver, according to one embodiment. Particularly, FIG. 3 illustrates the pad 100, a command module 200, the leg 210A-N, the voltage source 202, the resistor 206A-N, a p-channel MOSFET device 302A-N, and an n-channel MOSFET device 304A-N, according to one embodiment.

The command module 200 may control the mode of operation of the legs by turning on the positive and/or negative electrical switches. The p-channel MOSFET device 302A-N may be a positive switch device that may be used to switch the electronic signals. The n-channel MOSFET device 304A-N may be a negative switch device that may be used to switch the electronic signals.

In example embodiment, FIG. 3 illustrates the command module 200 may control (e.g., may turn on and/or turn off) the p-channel MOSFET device 302A-N (e.g., may turn on) of the legs 210A-N and the n-channel MOSFET device 304A-N (e.g., may turn off) of the legs 210A-N. The command module 200 associated with the legs 210A-N that may be coupled with the voltage source 202, the resistor 206A-N, and the ground 210 to a circuit board.

FIG. 4 is a systematic view of Thevinin termination mode, according to one embodiment. Particularly, FIG. 4 illustrates, the voltage source 202, the resistor 206A-N, the ground 212, the pad 100, the on-die termination circuit 108, the command module 200, a parallel coupling 402A-N, a positive switch on-mode 404A-B, a positive switch off-mode 406A-B, a negative switch off-mode 408A-B, a negative switch on-mode 410A-B, and a source load 412, according to one embodiment.

The parallel coupling 402A-N may illustrate the coupling of the resistor 206A-N of the number of legs parallel to the pad 100. The positive switch on-mode 404A-B may be an electrical device (e.g., a p-channel metal-oxide-semiconductor field-effect transistor (MOSFET device)) associated with a positive electronic signal line of the integrated circuit that may switch electronic signals to on-mode. The positive switch may be turned to on-mode by using the command module 200. The positive switch off-mode 406A-B may be an electrical device (e.g., a p-channel metal-oxide-semiconductor field-effect transistor (MOSFET device)) associated with a positive electronic signal line of the integrated circuit that may switch electronic signals to off-mode. The positive switch may be turned to off-mode by using the command module 200.

The negative switch off-mode 408A-B may be an electrical device (e.g., may be an n-channel metal-oxide-semiconductor field-effect transistor (MOSFET device)) associated with a negative electronic signal line of the integrated circuit that may switch electronic signals to off-mode. The negative switch may be turned to off-mode by using the command module 200. The negative switch on-mode 410A-B may be an electrical device (e.g., a p-channel metal-oxide-semiconductor field-effect transistor (MOSFET device)) associated with a negative electronic signal line of the integrated circuit that may switch electronic signals to on-mode. The negative switch may be turned to on-mode by using the command module 200. The load 520 may be any specified source impedance value in the pad 100 that may be associated with the coupled resistors 206A-N.

In example embodiment, the on-die termination circuit 108 may consist of the command module 200 that may control mode of operation of the legs by turning the positive electrical switch to on-mode and/or off-mode (e.g., positive switch on-mode 404A-B and/or positive switch off-mode 406A-B) and negative electrical switch to on-mode and/or off-mode (e.g., negative switch on-mode 410A-B and/or negative switch off-mode 408A-B). The leg of the on-die termination circuit 108 may be coupled with the voltage source 202 and leg of the on-die termination circuit 108 may be coupled with the ground 210.

The entirety of the resistors 206A-N may be associated in parallel to each other and coupled with the pad 100. The command module 200 may control the mode of operation of positive switch on-mode 404A-B, positive switch off-mode 406A-B, negative switch off-mode 408A-B, and negative switch on-mode 410A-B. The positive switch on-mode 404A-B may be coupled with the resistor 206A-N respectively and in turn the resistor 206A-N may be coupled with negative switch off-mode 408A-B respectively. The positive switch off-mode 406A-B may be coupled with the resistor 206C-D respectively and in turn the resistor 206C-D may be coupled with negative switch on-mode 410A-B respectively.

In one embodiment, the leg of the on-die termination circuit may be configured by coupling the positive electrical switch with the resistor 206A-N and coupling the resistor 206A-N with the negative electrical switch. The leg 210A-N may be coupled with the voltage source 202. The leg 210A-N may be coupled with the ground 210. The leg 210A-N may be located within the semiconductor integrated circuit 102A-N. The positive electrical switch may be associated with the positive electronic signal line of the integrated circuit (e.g., may be semiconductor integrated circuit 102A-N). The negative electrical switch may be associated with the negative electronic signal line of the integrated circuit.

The resistor 206A-N may be coupled to the circuit board. The legs 210A-N may be configured such that all the resistors 206A-N has the same potential difference across each end of the resistors 206A-N. The legs 210A-N may be associated with the command module 200. The command module 200 may control the mode of operation of legs by turning on the positive electrical switches and/or the negative electrical switches. The positive electrical switches of the legs 210A-N may be turned on by the command module 200. The negative electrical switches of the legs 210A-N may be turned off by the command module 200. The negative electrical switches of the legs 210A-N may be turned on by the command module 200.

The positive electrical switches of the legs 210A-N may be turned off by the command module 200. The legs 210A-N may be even in number. Half the positive electrical switches of the half of the legs may be turned on by the command module 200 while the negative electrical switches of the half of the legs may be turned off by the command module 200. The negative electrical switches of an other half of the legs may be turned on by the command module 200 while the positive electrical switches of the other half of the legs may be turned off by the command module 200. The Thevenin-equivalent resistance value of the on-die termination circuit as seen from the pad may be equal with the specified source resistance value. The number of legs may be the even number. The half of the even number of legs may be operated with the positive switch device (e.g., may be the positive switch on-mode 404A-N and the positive switch off-mode 406A-N) in the on-state and/or the negative switch device (e.g., may be negative switch on-mode 410A-N and negative switch off-mode 408A-N) in the off-state.

An other half of the even number of legs may be operated with the positive switch device in the off-state and the negative switch device in the on-state. The specified even number of legs may be operated to obtain the load impedance value as seen from the pad 100 equal to the specified source impedance value. All the legs may be operated with the positive switch device in the on-state and the negative switch device in the off-state. All the legs may be operated with the positive switch device in the off-state and/or the negative switch device in the on-state.

FIG. 5A is a systematic view of a driver mode ‘A’, according to one embodiment. Particularly, FIG. 5A illustrates the pad 100, the voltage source 202, the resistor 206A-N, the command module 200, the parallel coupling 402A-N, the positive switch on-mode 404A-N, the negative switch off-mode 408A-N, the load 520, a positive electronic signal line 530, and a negative electronic signal line 540, according to one embodiment.

The positive electronic signal line 530 may be a transmission line (e.g., may be circuit path for communication) that may carry positive electronic signal for positive electrical switch in the integrated circuit. The negative electronic signal line 540 may be a transmission line (e.g., may be circuit path for communication) that may carry negative electronic signal for negative electrical switch in the integrated circuit.

In example embodiment, FIG. 5A illustrates the drive mode ‘A’ that may include the command module 200 that has the voltage source 202. The command module 200 may enable the positive switch on-mode 404A-N that may be coupled with the resistor 206A-N coupled with the pad 100 that has load 520. The command module 200 may enable the negative switch off-mode 408A-N associated with the resistor 206A-N associated with the parallel coupling 402A-N coupled with load 520 that has load 520. The positive electronic signal line 530 may be associated with the positive switch on-mode 404A-N. The negative electronic signal line 540 may be associated with the negative switch off-mode 408A-N.

FIG. 5B is a systematic view of a driver mode ‘B’, according to one embodiment. Particularly, FIG. 5B illustrates pad 100, the voltage source 202, the resistor 206A-N, the command module 200, the parallel coupling 402A-N, the positive switch off-mode 406A-N, the negative switch on-mode 410A-N, and the load 520, according to one embodiment.

In example embodiment, the driver mode B may illustrate the positive electronic signal line 530 from the command module 200 may be associated with each of the positive switch off-mode 406A-N. The negative electronic signal line 540 from the command module 200 may be associated with the negative switch on-mode 410A-N. The resistor 206A-N may be coupled parallel to each other and in turn coupled with the pad 100. Each of the leg may consist of positive switch off-mode coupled 406A-N coupled with the resistor 206A-N and in turn the resistor 206A-N may be coupled with negative switch on-mode 410A-N, respectively.

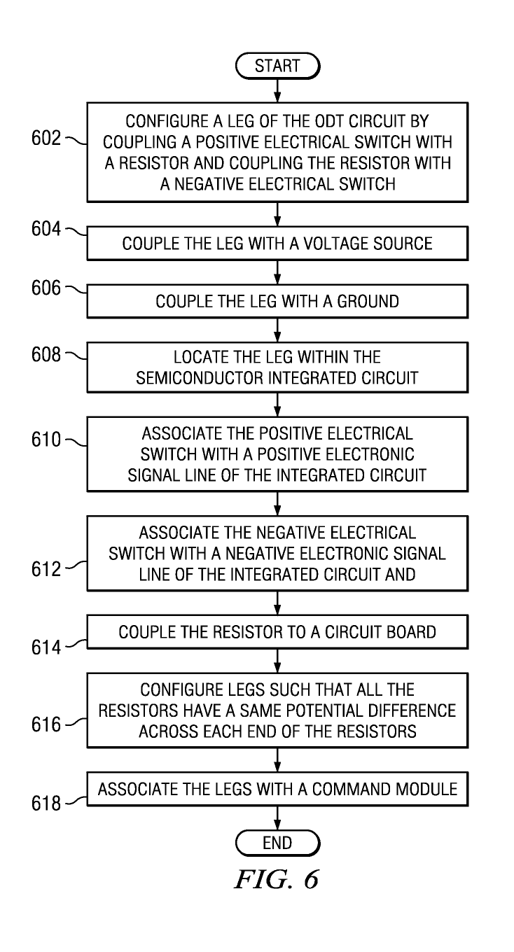

FIG. 6 is a process flow of configuring and coupling the leg of ODT (on-die termination) circuit, according to one embodiment. In operation 602, a leg (e.g., the leg 210A-N of FIG. 2) of the on-die termination circuit (e.g., the on-die termination circuit 108A-N of FIG. 1) may be configured by coupling a positive electrical switch (e.g., the p-channel MOSFET device 302A-N of FIG. 3) with a resistor (e.g., the resistor 206A-N of FIG. 2) and coupling the resistor 206A-N with a negative electrical switch (e.g., the n-channel MOSFET device 304A-N of FIG. 3). In operation 604, the leg 210A-N may be coupled with a voltage source (e.g., the voltage source 202 of FIG. 2).

In operation 606, the leg 210A-N may be coupled with a ground (e.g., the ground 210 of FIG. 2). In operation 608, the leg 210A-N may be located within the semiconductor integrated circuit 102A-N. In operation 610, the positive electrical switch may be associated with a positive electronic signal line (e.g., the positive electronic signal line 530 of FIG. 5) of the integrated circuit 102A-N. In operation 612, the negative electrical switch may be associated with a negative electronic signal line (e.g., the negative electronic signal line 540 of FIG. 5) of the integrated circuit 102A-N.

In operation 614, the resistor 206A-N may be coupled to a circuit board. In operation 616, the legs 210A-N may be configured such that all the resistors 206A-N have a same potential difference across each end of the resistors 206A-N. In operation 618, the legs 210A-N may be associated with a command module (e.g., the command module 200 of FIG. 3).

The command module 200 may control the mode of operation of legs 210A-N by turning on the positive electrical switches (e.g., P-channel MOSFET device 302A-N of FIG. 3) and/or the negative electrical switches (e.g., N-channel MOSFET 304A-N of FIG. 3). The positive electrical switches of the legs 210A-N may be turned on by the command module 200. The negative electrical switches of legs 210A-N may be turned off by the command module 200. The negative electrical switches of the legs 210A-N may be turned on by the command module 200.

The positive electrical switches of the legs 210A-N may be turned off by the command module 200. The legs 210A-N may be even in number. Half the positive electrical switches of a half of the legs 210A-N may be turned on by the command module 200 while the negative electrical switches of the half of the legs 210A-N may be turned off by the command module 200. The negative electrical switches of an other half of the legs 210A-N may be turned on by the command module 200 while the positive electrical switches of the other half of the legs 210A-N are turned off by the command module 200. The Thévenin-equivalent resistance value of the on-die termination circuit 108A-N as seen from the pad 100 may be equal with a specified source resistance value.

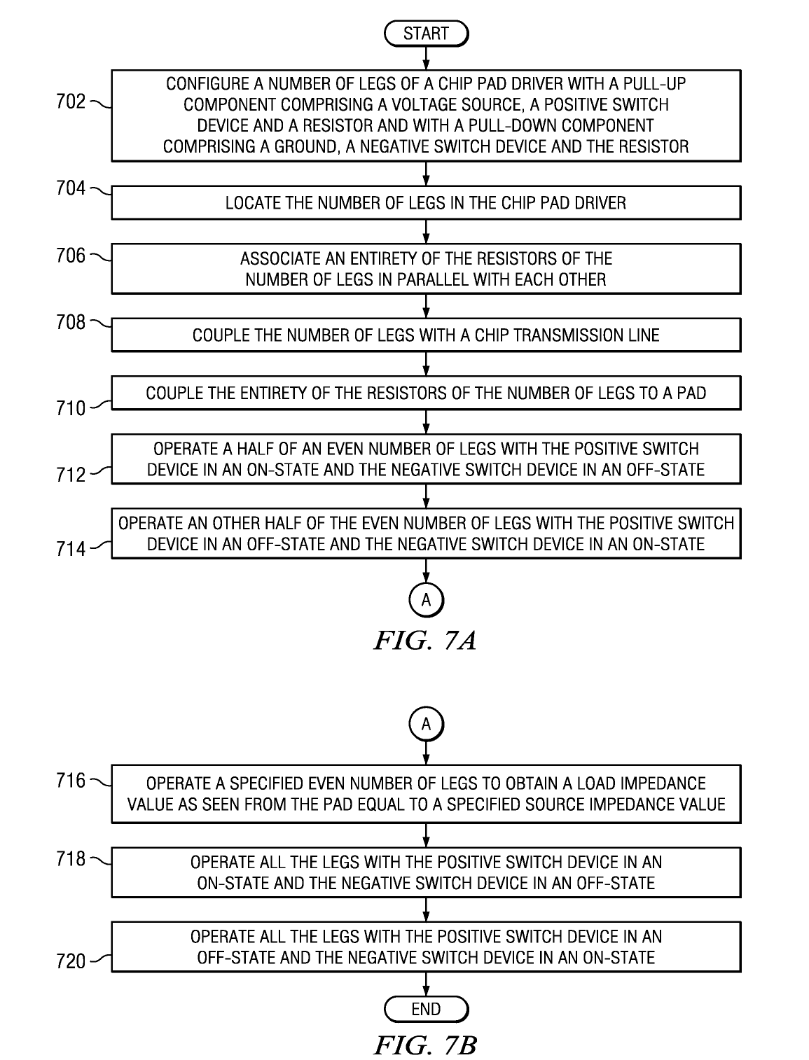

FIG. 7A is a process flow of operating all the legs with the positive switch device in an off-state and the negative switch device in an on-state, according to one embodiment. In operation 702, the number of legs 210A-N of a chip pad driver may be configured with a pull-up component (e.g., may be the pull-up circuit 204A-N of FIG. 2) comprising a voltage source (e.g., the voltage source 202 of FIG. 2), a positive switch device (e.g., may be a p-channel MOSFET device 302A-N of FIG. 3) and a resistor (e.g., the resistor 206A-N of FIG. 2) and with a pull-down component (e.g., may be the pull-down circuit 208A-N of FIG. 2) comprising a ground (e.g., the ground 210 of FIG. 2), a negative switch device (e.g., may be the n-channel MOSFET device 304A-N of FIG. 3) and the resistor 206A-N. In operation 704, the number of legs 210A-N may be located in the chip pad driver. In operation 706, an entirety of the resistors 206A-N of the number of legs 210A-N may be associated in parallel with each other. In operation 708, the number of legs 210A-N may be coupled with a chip transmission line (e.g., may be the signal transmission line 104A-N of FIG. 1). In operation 710, the entirety of the resistors 206A-N of the number of legs 210A-N may be coupled to a pad (e.g., the pad 100 of FIG. 1).

The number of legs 210A-N is an even number. In operation 712, a half of an even number of legs (e.g., of the legs 210A-N) may be operated with the positive switch device in an on-state (e.g., may be the positive switch on-mode 404A-N of FIG. 4) and/or the negative switch device in an off-state. In operation 714, an other half of the even number of legs (e.g., of the legs 210A-N) may be operated with the positive switch device in an off-state and the negative switch device in an on-state.

FIG. 7B is a continuation of process flow of FIG. 7A, illustrating additional operations, according to one embodiment. In operation 716, a specified even number of legs (e.g., of the legs 210A-N) may be operated to obtain a load impedance value as seen from the pad 100 equal to a specified source impedance value. In operation 718, all the legs 210A-N may be operated with the positive switch device in an on-state and the negative switch device in an off-state. In operation 720, all the legs 210A-N may be operated with the positive switch device in an off-state and/or the negative switch device in an on-state.

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium). For example, the various electrical structure and methods may be embodied using transistors, logic gates, and electrical circuits (e.g., application specific integrated (ASIC) circuitry and/or in Digital Signal Processor (DSP) circuitry).

Particularly, the on-die termination circuits 108A-N, and the command module 200 of FIG. 1-7 may be enabled using software and/or using transistors, logic gates, and electrical circuits (e.g., application specific integrated ASIC circuitry) such as an on-die termination circuit, a command circuit, the semiconductor integrated circuit 102A-N, the pull-up circuit 204A-N, the pull-down circuit 208A-N, and other circuit.

In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed is:

1. A system of terminating a transmission line comprising:
a pull-up circuit located within the chip comprising a voltage source and a positive switch device coupled with the transmission line of the chip;
a pull-down circuit located within the chip comprising a ground and a negative switch device coupled with the transmission line of the chip and; and
a resistor located within the chip coupled with the voltage source, the positive switch device, the ground, the negative switch device;
a pad coupled with the resistor to terminate the transmission line of the chip.

2. The system of claim 1 further comprising a plurality of resistors coupled in parallel with each other and wherein each resistor of the plurality of resistors is coupled with a corresponding pull-up circuit and a corresponding pull-down circuit.

3. The system of claim 2 further comprising an impedance module to determine a load impedance value as seen from the pad that matches a source impedance value and wherein the plurality of resistors is an even number of resistors.

4. The system of claim 3 further comprising a command module to operate half of the pull-up circuits in an on mode while simultaneously operating an equal even number of pull down circuits in an off mode and wherein a pull-up circuit and a pull down circuit coupled to the resistor cannot both simultaneously be in the on mode.

5. The system of claim 4 wherein a specified even number of pull-up circuits, pull down circuits and resistors of a particular impedance value are used to obtain the load impedance value as seen from the pad.

6. The system of claim 2:
wherein all the pull-up circuits in the on mode and all the pull down circuits are operated in the off mode, and
wherein an impedance value of the in parallel plurality of resistors matches a specified load impedance value.

7. The system of claim 2:
wherein all the pull-up circuits in the off mode and all the pull down circuits are operated in the on mode, and
wherein the impedance value of the in parallel to plurality of resistors in parallel matches a specified load impedance value.

8. The system of claim 1 wherein the positive switch device is a p-channel metal-oxide-semiconductor field-effect transistor (MOSFET) device used to switch electronic signals and the negative switch device is an n-channel MOSFET device used to switch electronic signals.

9. A method of an on-die termination (ODT) circuit of a semiconductor integrated circuit comprising:
configuring a leg of the ODT circuit by coupling a positive electrical switch with a resistor and coupling the resistor with a negative electrical switch;
coupling the leg with a voltage source;
coupling the leg with a ground;
locating the leg within the semiconductor integrated circuit;
associating the positive electrical switch with a positive electronic signal line of the integrated circuit;
associating the negative electrical switch with a negative electronic signal line of the integrated circuit; and
coupling the resistor to a circuit board.

10. The method of claim 9 further comprising a plurality of legs configured such that all the resistors have a same potential difference across each end of the resistors.

11. The method of claim 10 further comprising:
associating the plurality of legs with a command module, and
wherein the command module controls the mode of operation of the plurality of legs by turning on at least one of the positive electrical switches and the negative electrical switches.

12. The method of claim 11:
wherein the positive electrical switches of the plurality of legs are turned on by the command module, and
wherein the negative electrical switches of the plurality of legs are turned off by the command module.

13. The method of claim 11:
wherein the negative electrical switches of the plurality of legs are turned on by the command module, and
wherein the positive electrical switches of the plurality of legs are turned off by the command module.

14. The method of claim 11:
wherein the plurality of legs is even in number,
wherein half the positive electrical switches of a half of the legs are turned on by the command module while the negative electrical switches of the half of the legs are turned off by the command module, and
wherein the negative electrical switches of an other half of the legs are turned on by the command module while the positive electrical switches of the other half of the legs are turned off by the command module.

15. The method of claim 14 wherein a Thévenin-equivalent resistance value of the ODT circuit as seen from an pad is equal with a specified source resistance value.

16. A method of a circuit technique comprising:
configuring a number of legs of a chip pad driver with a pull-up component comprising a voltage source, a positive switch device and a resistor and with a pull-down component comprising a ground, a negative switch device and the resistor;
locating the number of legs in the chip pad driver;
associating an entirety of the resistors of the number of legs in parallel with each other;
coupling the number of legs with a chip transmission line; and
coupling the entirety of the resistors of the number of legs to a pad.

17. The method of claim 16 further comprising:
wherein the number of legs is an even number.
operating a half of an even number of legs with the positive switch device in an on-state and the negative switch device in an off-state, and
operating an other half of the even number of legs with the positive switch device in an off-state and the negative switch device in an on-state.

18. The method of claim 17 further comprising operating a specified even number of legs to obtain a load impedance value as seen from the pad equal to a specified source impedance value.

19. The method of claim 16 further comprising operating all the legs with the positive switch device in an on-state and the negative switch device in an off-state.

20. The method of claim 16 further comprising operating all the legs with the positive switch device in an on-state and the negative switch device in an on-state.
